(19) United States
(12) Patent Application Publication
(10) Pub. No.: US 2025/0314709 A1
(43) Pub. Date: Oct. 9, 2025

(54) Battery Diagnosis Apparatus and Operating Method Thereof

(71) Applicant: LG Energy Solution, Ltd., Seoul (KR)

(72) Inventors: Ha Eun Byun, Daejeon (KR); Cheol Taek Kim, Daejeon (KR); Jung Uk Park, Daejeon (KR); Jung Hwan Choi, Daejeon (KR); Young Min Kim, Daejeon (KR)

(73) Assignee: LG Energy Solution, Ltd., Seoul (KR)

(21) Appl. No.: 19/098,678

(22) Filed: Apr. 2, 2025

(30) Foreign Application Priority Data
Apr. 3, 2024 (KR) 10-2024-0045175
May 7, 2024 (KR) 10-2024-0059709
Apr. 2, 2025 (KR) 10-2025-0042886

(51) Int. Cl. G01R 31/392; G01R 31/3835; G01R 31/396

(52) U.S. Cl. CPC G01R 31/392; G01R 31/3835; G01R 31/396

(57) ABSTRACT

The technology generally relates to a battery diagnosis approach where an abnormality of a battery may be detected using battery OCV information, reducing the processing cost and memory usage involved in diagnosing batteries while maintaining or improving accuracy. Battery abnormalities may be diagnosed in shorter periods of time, reducing the chance of fires occurring due to the battery abnormality.

### CROSS-REFERENCE TO RELATED APPLICATIONS

The present application claims priority to Korean Patent Application No. 10-2024-0045175 filed on Apr. 3, 2024, Korean Patent Application No. 10-2024-0059709 filed on May 7, 2024, and Korean Patent Application No. 10-2025-0042886 filed on Apr. 2, 2025 all of which is incorporated herein by reference.

### BACKGROUND

Secondary batteries are chargeable/dischargeable batteries and may include nickel (Ni)/cadmium (Cd) batteries, Ni/metal hydride (MH) batteries, and/or lithium-ion batteries, as examples. Among the secondary battery examples, lithium-ion batteries have a higher energy density than Ni/Cd batteries or Ni/MH batteries. Moreover, lithium-ion batteries may be manufactured to be small and lightweight. Secondary batteries may be used in various devices. For example, secondary batteries may be used for mobile devices, e.g., mobile phones, laptop computers, smart phones, smart pads, for vehicles, e.g., electric vehicles (EV), hybrid electric vehicles (HEV), plug-in HEV (PHEV)), and/or for large-volume energy storage systems (ESS).

These batteries may be managed and controlled in terms of states and operations by a battery management system. The battery management system may be included together with a battery in one device or may be part of a separate device. For example, the battery management system may be implemented as a separate server device. In this example, the battery management system may collect battery data and device data from the device, e.g., mobile device, vehicle, and/or storage system, and manage and control the battery using the collected data.

When a short circuit or other failure occurs inside a battery, the possibility of damage to the device, including the battery itself, may increase. To reduce the possibility of damage to the device, abnormal states of the battery may be detected. Abnormal states of the battery may be detected by using numerous factors, including state of charge (SOC), current, capacity, and open circuit voltage (OCV) information. However, using so many factors may excessively increase processing costs and memory usage, particularly in the example of the battery management system implemented in the server device, as the battery management system has to collect and process data from the numerous factors. But removing some of these factors may reduce the accuracy or otherwise cause difficulty in detecting abnormal states of the battery.

### SUMMARY

The technology generally relates to a battery diagnosis approach where an abnormality of a battery may be detected using battery OCV information, reducing the processing cost and memory usage involved in diagnosing batteries while maintaining or improving accuracy. Battery abnormalities may be diagnosed in shorter periods of time, reducing the chance of fires occurring due to the battery abnormality.

Aspects of the disclosure provide for a battery diagnosis apparatus including: an interface configured to obtain open circuit voltage (OCV) data of a battery cell; and one or more processors configured to: calculate a plurality of OCV deviations based on the OCV data, the OCV deviations indicating a difference between an average OCV of a plurality of battery cells and an OCV of the battery cell at a plurality of points in time; calculate a plurality of OCV deviation variances based on the plurality of OCV deviations, the OCV deviation variances indicating a degree of change of the plurality of OCV deviations at the plurality of points in time; calculate an OCV moving average based on the plurality of OCV deviation variances by applying a weighted moving average to the plurality of OCV deviation variances; and diagnose an abnormality of the battery cell based on the OCV moving average.

In some examples, the one or more processors are further configured to: determine that a k^{th} OCV deviation variance corresponding to a k^{th} point in time among the plurality of points in time is less than a first threshold OCV deviation variance; determine that a (k−1)^{th} OCV deviation corresponding to a (k−1)^{th} point in time previous to the k^{th} point in time is greater than or equal to a threshold OCV deviation; and change the kth OCV deviation variance into a predetermined OCV deviation variance; wherein applying the weighted moving average to the plurality of OCV deviation variances comprises the predetermined OCV deviation variance.

In some examples, diagnosing an abnormality of the battery cell includes comparing the OCV moving average with a threshold moving average.

In some examples, the one or more processors are further configured to: determine that the OCV moving average is less than the threshold moving average; and increase a diagnosis count by a first increment; wherein diagnosing an abnormality of the battery cell is based on comparing the diagnosis count with a threshold count.

In some examples, the one or more processors are further configured to: calculate a second increment based on a degree to which the OCV moving average is less than the threshold moving average; and increase the diagnosis count by the second increment.

In some examples, the one or more processors are further configured to: determine that the OCV moving average is greater than or equal to the threshold moving average; and reduce the diagnosis count.

In some examples, the one or more processors are further configured to: determine that an OCV deviation variance is less than a second threshold OCV deviation variance; and change the OCV deviation variances less than the second threshold OCV deviation variance to the second threshold OCV deviation variance; wherein applying the weighted moving average to the plurality of OCV deviation variances comprises OCV deviation variance changed to the second threshold OCV deviation variance.

In some examples, the weighted moving average is an exponentially weighted moving average.

In some examples, the OCV data compensates for a balancing process performed on the battery cell based on a balancing capacity.

In some examples, the balancing capacity corresponds to an accumulated discharging capacity from the balancing process over a period of time.

Aspects of the disclosure provide for a battery diagnosis method including: receiving, by one or more processors, open circuit voltage (OCV) data of a battery cell; calculating, by the one or more processors, a plurality of OCV deviations based on the OCV data, the OCV deviations indicating a difference between an average OCV of a plurality of battery cells and an OCV of the battery cell at a plurality of points in time; calculating, by the one or more processors, a plurality of OCV deviation variances based on the plurality of OCV deviations, the OCV deviation variances indicating a degree of change of the plurality of OCV deviations at the plurality of points in time; calculating, by the one or more processors, an OCV moving average based on the plurality of OCV deviation variances by applying a weighted moving average to the plurality of OCV deviation variances; and diagnosing, by the one or more processors, an abnormality of the battery cell based on the OCV moving average.

In some examples, the method further includes: determining, by the one or more processors, that a k^{th} OCV deviation variance corresponding to a k^{th} point in time among the plurality of points in time is less than a first threshold OCV deviation variance; determining, by the one or more processors, that a (k−1)^{th} OCV deviation corresponding to a (k−1)^{th} point in time previous to the k^{th} point in time is greater than or equal to a threshold OCV deviation; and changing, by the one or more processors, the kth OCV deviation variance into a predetermined OCV deviation variance; wherein applying the weighted moving average to the plurality of OCV deviation variances comprises the predetermined OCV deviation variance.

In some examples, diagnosing an abnormality of the battery cell includes comparing the OCV moving average with a threshold moving average.

In some examples, the method further includes: determining, by the one or more processors, that the OCV moving average is less than the threshold moving average; and increasing, by the one or more processors, a diagnosis count by a first increment; wherein diagnosing an abnormality of the battery cell is based on comparing the diagnosis count with a threshold count.

In some examples, the method further includes: calculating, by the one or more processors, a second increment based on a degree to which the OCV moving average is less than the threshold moving average; and increasing, by the one or more processors, the diagnosis count by the second increment.

In some examples, the method further includes: determining, by the one or more processors, that the OCV moving average is greater than or equal to the threshold moving average; and reducing, by the one or more processors, the diagnosis count.

In some examples, the method further includes: determining, by the one or more processors, that an OCV deviation variance is less than a second threshold OCV deviation variance; and changing, by the one or more processors, the OCV deviation variances less than the second threshold OCV deviation variance to the second threshold OCV deviation variance; wherein applying the weighted moving average to the plurality of OCV deviation variances comprises OCV deviation variance changed to the second threshold OCV deviation variance.

In some examples, the weighted moving average is an exponentially weighted moving average.

In some examples, the OCV data compensates for a balancing process performed on the battery cell based on a balancing capacity, the balancing capacity corresponding to an accumulated discharging capacity from the balancing process over a period of time.

Aspects of the disclosure provide for a non-transitory computer readable medium storing instructions that, when executed by one or more processors, cause the one or more processors to perform a battery diagnosis method, the method including: receiving open circuit voltage (OCV) data of a battery cell; calculating a plurality of OCV deviations based on the OCV data, the OCV deviations indicating a difference between an average OCV of a plurality of battery cells and an OCV of the battery cell at a plurality of points in time; calculating a plurality of OCV deviation variances based on the plurality of OCV deviations, the OCV deviation variances indicating a degree of change of the plurality of OCV deviations at the plurality of points in time; calculating an OCV moving average based on the plurality of OCV deviation variances by applying a weighted moving average to the plurality of OCV deviation variances; and diagnosing an abnormality of the battery cell based on the OCV moving average.

### BRIEF DESCRIPTION OF THE DRAWINGS

FIG. 1 is a block diagram of a battery diagnosis apparatus according to aspects of the disclosure.

FIG. 2 is a block diagram of the battery diagnosis apparatus calculating a determination value according to aspects of the disclosure.

FIGS. 3A to 3C are graphs illustrating the battery diagnosis apparatus diagnosing an abnormality of a battery cell according to aspects of the disclosure.

FIG. 4 is an operating flowchart of the battery diagnosis apparatus according to aspects of the disclosure.

FIG. 5 is a computing system for implementing the battery diagnosis apparatus according to aspects of the disclosure.

### DETAILED DESCRIPTION

Aspects of the disclosure are described with reference to the accompanying drawings. The disclosure may be modified in various forms and have various examples, and specific examples thereof are shown by way of drawings and description below. It should be understood, however, that there is no intent to limit the disclosure to the specific examples, but on the contrary, the disclosure is to cover all modifications, equivalents, and alternatives falling within the spirit and technical scope of the disclosure. Like reference numerals refer to like elements throughout the description of the figures. It is to be understood that a singular form of a noun corresponding to an item may include one or more of the things, unless the relevant context clearly indicates otherwise.

As used herein, each of such phrases as “A or B”, “at least one of A and B”, “at least one of A or B”, “A, B, or C”, “at least one of A, B, and C”, and “at least one of A, B, or C” may include any one of or all possible combinations of the items enumerated together in a corresponding one of the phrases. Such terms as “1st”, “2nd”, “first”, “second”, “A”, “B”, “(a)”, or “(b)” may be used to simply distinguish a corresponding component from another, and does not limit the components in other aspects, e.g., importance or order, unless mentioned otherwise.

As used herein, it will be understood that when an element is referred to as being “coupled” or “connected” to another element, it can be directly coupled or connected to the other element or an intervening element may be present. The connection may be wired or wireless. In contrast, when an element is referred to as being “directly coupled” or “directly connected” to another element, there is no intervening element present.

The terms used herein are for the purpose of describing specific examples only and are not intended to limit the disclosure. It will be further understood that the terms “comprises”, “comprising”, “includes”, “including” and/or “having”, when used herein, specify the presence of stated features, integers, steps, operations, constitutional elements, components and/or combinations thereof, but do not preclude the presence or addition of one or more other features, integers, steps, operations, constitutional elements, components, and/or combinations thereof.

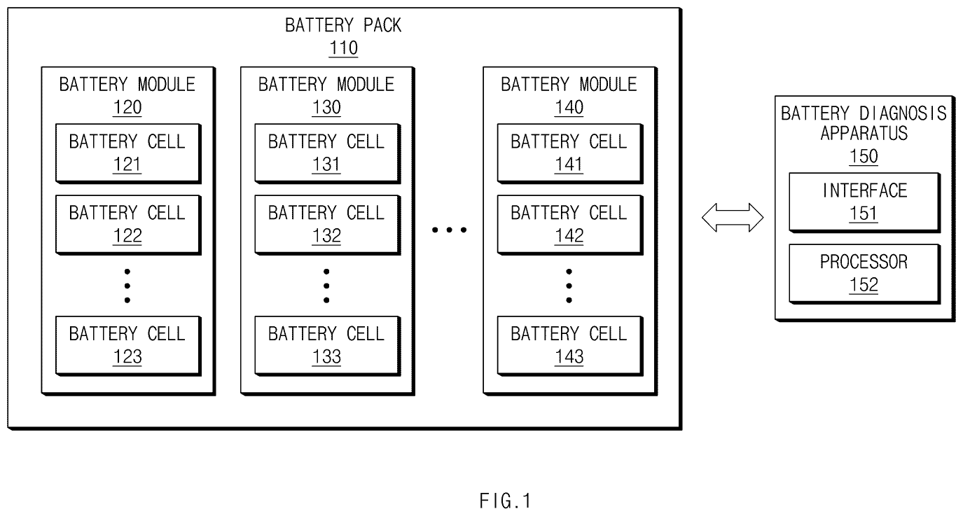

FIG. 1 is a block diagram of a battery diagnosis apparatus 150 and battery pack 110 according to aspects of the disclosure. The battery pack 110 may include a plurality of modules 120, 130, and 140, which respectively include a plurality of battery cells 121, 122, 123, 131, 132, 133, 141, 142, and 143. The plurality of battery cells may be connected to one another in series and/or in parallel. As an example, the battery pack 110 may be a battery mounted inside an electric vehicle to supply power to the electric vehicle.

The battery diagnosis apparatus 150 may diagnose an abnormality of a battery unit based on OCV data obtained from a battery unit. The battery unit may mean the battery pack 110, one or more of the battery modules 120, 130, or 140, or one or more of the battery cells 121, 122, 123, 131, 132, 133, 141, 142, or 143.

The battery diagnosis apparatus 150 may be formed integrally with the battery unit. For example, the battery diagnosis apparatus 150 may be included in a battery management system of the battery unit. Alternatively, or additionally, the battery diagnosis apparatus 150 may be formed separately from the battery unit. For example, the battery diagnosis apparatus 150 may be implemented as an external server connected to the battery unit through a wireless network. As examples, the battery diagnosis apparatus 150 may also be included in a battery management system in a vehicle, a server, a cloud, a charger, and/or a charger/discharger.

The battery diagnosis apparatus 150 may include an interface 151 and one or more processors 152. The interface 151 may obtain OCV data of the battery cells 121, 122, 123, 131, 132, 133, 141, 142, and/or 143. For example, the interface 151 may obtain information regarding voltage, current, and/or temperature of the battery cells 121, 122, 123, 131, 132, 133, 141, 142, and/or 143 and configure OCV data based on the obtained information. Here, the interface 151 may include a sensor for obtaining the information regarding the voltage, current, and/or temperature and a processor for configuring the OCV data based on the obtained information. In another example, the interface 151 may receive the OCV data of the battery cells 121, 122, 123, 131, 132, 133, 141, 142, and/or 143 as obtained by the battery unit. Here, the interface 151 may include a communication circuit capable of performing wired and/or wireless network communication.

A balancer (not shown) may be configured to perform a balancing process, e.g., discharging, on at least some battery cells with unbalanced voltages. The OCV data may compensate for the balancing process performed on the battery cells by using a balancing capacity. The compensated OCV data may be an estimated value of the OCV data when the balancing process is not executed. For example, an SOC estimated value of each battery cell may be determined by applying an SOC-OCV map to the OCV data of each battery cell, the SOC estimated value of each battery cell may be compensated for by summing an SOC variance corresponding to the balancing capacity to the SOC estimated value of each battery cell, and the SOC-OCV map may be applied to the compensated SOC estimated value of each battery cell to determine the OCV data.

The balancing capacity may correspond to an accumulated discharging capacity of the battery cells based on the balancing process. For example, the balancing capacity may be an accumulated value of the discharging capacity of the battery cell through the balancing process conducted during a specific period, e.g., a total discharging capacity during the specific period. For example, the balancing capacity of the battery cell on which the balancing process is not performed during the specific period may be 0.

By compensating for the balancing process in the OCV data, a battery cell with an abnormality may be accurately detected even in a state where the unbalanced voltage state is resolved by the balancing process.

The processor 152 may be implemented as one processor or multiple separate processors. The processor 152 may process or compute various data as well as execute software to control one or more hardware or software components of the battery diagnosis apparatus 150. The processor 152 may calculate a determination value, e.g., an OCV deviation, an OCV deviation variance, an OCV moving average, and/or a diagnosis count, based on the OCV data obtained by the interface 151. The processor 152 may extract OCV data in a designated voltage range and calculate the determination value based on the extracted OCV data.

The processor 152 may diagnose an abnormality of the battery unit based on the calculated determination value. The processor 152 may diagnose an abnormality of the battery unit by comparing the determination value with a corresponding threshold value. For example, the processor 152 may diagnose the battery unit as an abnormal battery unit when the determination value, e.g., a diagnosis count, is greater than or equal to a threshold value, e.g., 40.

The battery diagnosis apparatus 150 may transmit a battery diagnosis result externally, e.g., to a cloud server and/or a user terminal. The cloud server may provide a service for providing the battery diagnosis result to one or more users. A user terminal may be a personal computer (PC) or a smartphone, as examples. The battery diagnosis apparatus 150 may provide the battery diagnosis result to the user terminal through 10 communication unit (not shown). The battery diagnosis apparatus 150 may provide the battery diagnosis result through a display provided in a vehicle or on a charger, as examples. The battery diagnosis apparatus 150 may further perform a correction in response to diagnosing an abnormality in a battery. The correction may include isolating the abnormal battery from the other batteries via electrical and/or mechanical isolation.

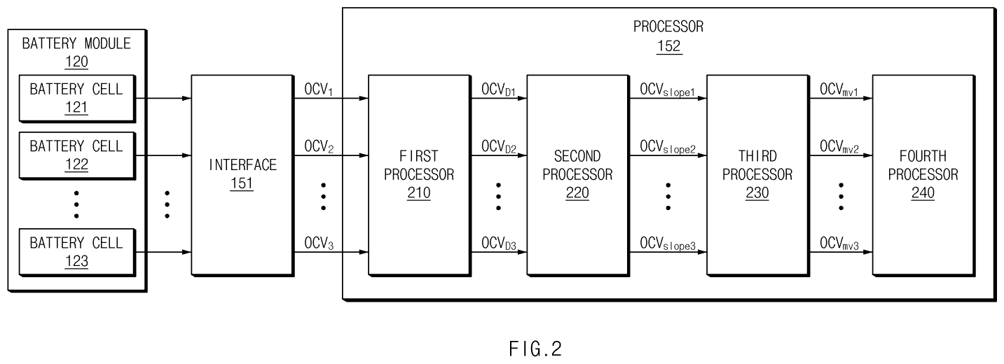

FIG. 2 is a block diagram of the battery diagnosis apparatus calculating a determination value according to aspects of the disclosure. The processor 152 may include a first processor 210, a second processor 220, a third processor 230, and a fourth processor 240.

The interface 151 may transmit OCV data of a plurality of battery cells to the first processor 210. For example, the interface 151 may transmit OCV data OCV1, OCV2, and OCV3 of the plurality of battery cells 121, 122, and 123 of a battery module 120 to the first processor 210. For simplicity, one battery module 120 will be described as an example, but the number of battery modules is not limited thereto.

The first processor 210 may calculate, based on the OCV data OCV1, OCV2, and OCV3, for respective battery cells 121, 122, and 123, a plurality of OCV deviations OCV_{D1}, OCV_{D2}, and OCV_{D3}. The OCV deviations may indicate differences between an average OCV corresponding to a plurality of points in time and the OCV data OCV1, OCV2, and OCV3 of the respective battery cells 121, 122, and 123. For example, the first processor 210 may calculate an OCV deviation OCV_{D1_1} indicating a difference between an average OCV (e. g., (OCV_{1_1}+OCV_{2_1}+OCV_{3_1})/3)) of the plurality of battery cells 121, 122, and 123 at a first point in time and OCV data OCV1_1 of the battery cell 121 at the first point in time. As another example, the first processor 210 may calculate an OCV deviation OCV_{D1_2} indicating a difference between an average OCV (e.g., (OCV_{1_2}+OCV_{2_2}+OCV_{3_2})/3)) of the plurality of battery cells 121, 122, and 123, corresponding to a second point in time, and OCV data OCV_{1_2} of the battery cell 121, corresponding to the second point in time.

The first processor 210 may transmit the plurality of calculated OCV deviations OCV_{D1}, OCV_{D2}, and OCV_{D3} corresponding to a plurality of points in time to the second processor 220. The second processor 220 may obtain a plurality of OCV deviation variances OCVₛₗₒₚₑ₁, OCVₛₗₒₚₑ₂, and OCVₛₗₒₚₑ₃. The OCV deviation variances may indicate degrees of change of a plurality of OCV deviations for a plurality of points in time for a plurality of battery cells. Herein, the plurality of OCV deviation variances OCVₛₗₒₚₑ₁, OCVₛₗₒₚₑ₂, and OCVₛₗₒₚₑ₃ may respectively correspond to the plurality of battery cells 121, 122, and 123. For example, the second processor 220 may obtain the plurality of OCV deviation variances OCVₛₗₒₚₑ₁ of the battery cell 121 at the plurality of points in time based on the plurality of OCV deviations OCV_{D1} of the battery cell 121.

For example, the plurality of OCV deviation variances may be slopes of the plurality of OCV deviations for each of the plurality of points in time. For example, a k^{th} OCV deviation variance of the battery cell 121 corresponding to a k^{th} point in time may be a value obtained by dividing a value, obtained by subtracting a (k−1)^{th} OCV deviation corresponding to a (k−1)^{th} point in time from a k^{th} OCV deviation corresponding to a k^{th} point in time, by an interval between the k^{th} point in time and the (k−1)^{th} point in time. As another example, the plurality of OCV deviation variances may be differences between the plurality of OCV deviations for each of the plurality of points in time. For example, the k^{th} OCV deviation variance of the battery cell 121 corresponding to the k^{th} point in time may be a value obtained by subtracting the (k−1)^{th} OCV deviation corresponding to the (k−1)^{th} point in time from the k^{th} OCV deviation corresponding to the k^{th} point in time.

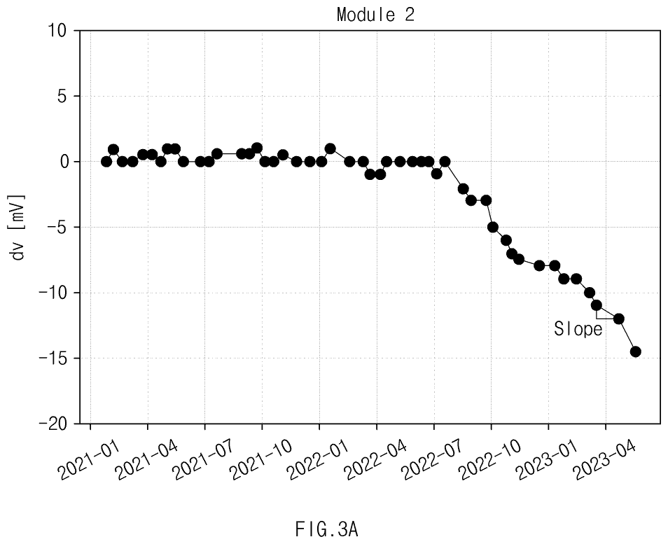

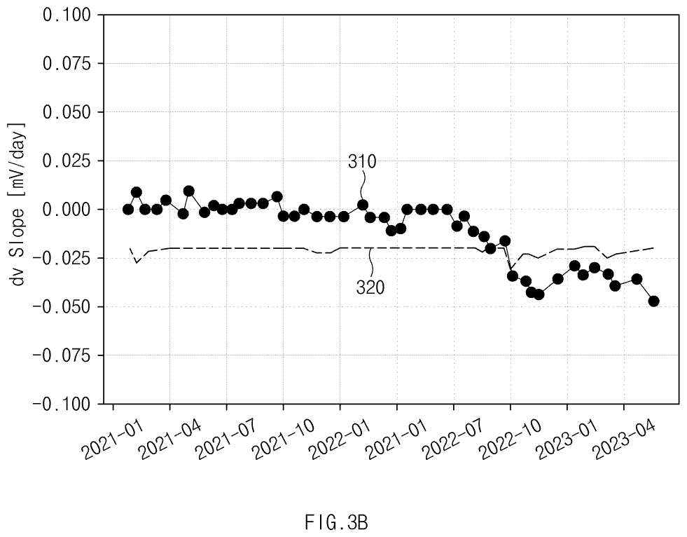

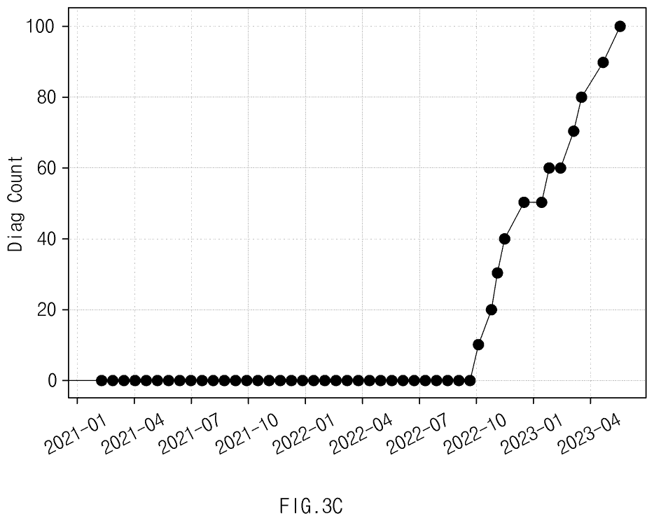

FIG. 3A depicts a graph showing OCV deviations for each of a plurality of points in time for a battery cell. The graph illustrates how the plurality of OCV deviation variances of the specific battery cell corresponding to the plurality of points in time may be obtained. FIG. 3A shows an OCV deviation variance having a specific period calculated based on OCV data obtained at specific intervals, e.g., 10 days. A horizontal axis indicates time with a scale corresponding to three months, and a vertical axis indicates a voltage (mV). While described that OCV data is obtained at specific intervals, aperiodic obtaining of the OCV data is not excluded from aspects of the disclosure.

The second processor 220 may transmit the plurality of calculated OCV deviation variances OCVₛₗₒₚₑ₁, OCVₛₗₒₚₑ₂, and OCVₛₗₒₚₑ₃ to the third processor 230. The third processor 230 may obtain OCV moving averages OCVₘᵥ₁, OCVₘᵥ₂, and OCVₘᵥ₃ by applying a weighted moving average, e.g., an exponentially weighted moving average, to the plurality of OCV deviation variances OCVₛₗₒₚₑ₁, OCVₛₗₒₚₑ₂, and OCVₛₗₒₚₑ₃. For example, the third processor 230 may obtain the OCV moving average OCVₘᵥ₁ by applying the weighted moving average to the plurality of OCV deviation variances OCVₛₗₒₚₑ₁ of the battery cell 121.

When the k^{th} OCV deviation variance corresponding to the k^{th} point in time among the plurality of points in time is less than a first threshold OCV deviation variance and the (k−1)^{th} OCV deviation corresponding to the (k−1)^{th} point in time previous to the k^{th} point in time is greater than or equal to a threshold OCV deviation, the third processor 230 may change the k^{th} OCV deviation variance into a specific OCV deviation variance and apply the weighted moving average to the plurality of OCV deviation variances to obtain the OCV moving average. For example, when a k^{th} OCV deviation variance OCV_{slope1_k} of the battery cell 121 corresponding to the k^{th} point in time among the plurality of points in time is less than the first threshold OCV deviation variance and a (k−1)^{th} OCV deviation OCV_{D1_(k-}1) of the battery cell 121 corresponding to the (k−1)^{th} point in time previous to the k^{th} point in time is greater than or equal to the threshold OCV deviation, the third processor 230 may update the k^{th} OCV deviation variance OCV_{slope1_k} into a specific OCV deviation variance and apply the weighted moving average to the plurality of OCV deviation variances to obtain the OCV moving average. For example, the first threshold OCV deviation variance may be set to −0.2, the threshold OCV deviation may be set to 0, and the specific deviation variance may be set to 0. By changing OCV deviation variance based on these thresholds, an over-detection rate that may occur due to the OCV deviation variance having an excessively high absolute value may be reduced.

The third processor 230 may change some OCV deviation variances that are less than a second threshold OCV deviation variance into the second threshold OCV deviation variance and apply the weighted moving average to the plurality of OCV deviation variances to obtain the OCV moving average. For example, the third processor 230 may change some OCV deviation variances that are less than the second threshold OCV deviation variance, among the plurality of OCV deviation variances OCVₛₗₒₚₑ₁ of the battery cell 121, into the second threshold OCV deviation variance and apply the weighted moving average to the plurality of OCV deviation variances to obtain the OCV moving average corresponding to the battery cell 121. For example, the second threshold OCV deviation variance may be set to −0.7. By changing OCV deviation variance based on this threshold, an over-detection rate that may occur due to the OCV deviation variance having an excessively high absolute value may be reduced.

The third processor 230 may transmit the calculated OCV moving averages OCVₘᵥ₁, OCVₘᵥ₂, and OCVₘᵥ₃ to the fourth processor 240. The fourth processor 240 may diagnose an abnormality of the battery cells 121, 122, and 123 based on the respective OCV moving averages OCVₘᵥ₁, OCVₘᵥ₂, and OCVₘᵥ₃. For example, the fourth processor 240 may diagnose an abnormality of the battery cell 121 based on the OCV moving average OCVₘᵥ₁ of the battery cell 121.

The fourth processor 240 may diagnose an abnormality of the battery cell by comparing the OCV moving averages OCVₘᵥ₁, OCVₘᵥ₂, and OCVₘᵥ₃ with a threshold moving average. For example, the fourth processor 240 may diagnose abnormality of the battery cell 121 based on a result of comparing the OCV moving average OCVₘᵥ₁ of the battery cell 121 with the threshold moving average. The threshold moving average may be determined by a product of a first preset value and a standard deviation of OCV moving averages of a specific battery module corresponding to a plurality of points in time added to an average of the OCV moving averages of the specific battery module. The result thereof may be compared with a second preset value to select a lesser of the two values, and the selected value may be compared with a third preset value to determine the greater value of the two values to be the threshold moving average. For example, the first preset value may be −6, the second preset value may be −0.02, and the third preset value may be −0.05. The standard deviation and the average may be calculated based on a value excluding a maximum value and a minimum value among OCV moving averages of the specific battery module corresponding to the plurality of points in time.

FIG. 3B depicts a graph showing OCV deviation variances for each of a plurality of points in time for a battery cell. A horizontal axis indicates time with a scale corresponding to three months, and a vertical axis indicates a slope (mV/day). An OCV moving average 310 may be identified as the result of applying an exponentially weighted moving average to the OCV deviation variance for each of the plurality of points in time, obtained based on the OCV deviation for each of the plurality of points in time for the specific battery cell of FIG. 3A. A threshold moving average 320 for comparison with the OCV moving average may also be identified.

When the OCV moving average OCVₘᵥ₁, OCVₘᵥ₂, and/or OCVₘᵥ₃ is less than the threshold moving average, the fourth processor 240 may increase a diagnosis count by a first increment and diagnose an abnormality of the battery cell 121, 122, and/or 123 based on a result of comparing the diagnosis count with a threshold count. For example, when the OCV moving average OCVₘᵥ₁ of the first battery cell 121 is less than the threshold moving average, the fourth processor 240 may increase a diagnosis count corresponding to the battery cell 121 by a first increment, e.g., 10, and diagnose abnormality of the battery cell 121, 122, and/or 123 based on a result of comparing the increased diagnosis count with the threshold count.

When a diagnosis count increase condition is further satisfied in a state where the OCV moving average OCVₘᵥ₁, OCVₘᵥ₂, and/or OCVₘᵥ₃ is less than the threshold moving average, the fourth processor 240 may increase the diagnosis count by the first increment. The diagnosis count increase condition for increasing a diagnosis count based on OCV data corresponding to a specific point in time may include (i) when an OCV deviation of a specific battery cell corresponding to the specific point in time is less than an OCV deviation corresponding to an immediately previous point in time and an OCV deviation corresponding to the immediately previous point in time is less than a preset value (e.g., 0), and (ii) the number of OCV deviations of the specific battery cell is greater than or equal to a predetermined number and a data accumulative collection period is greater than or equal to a predetermined period. The fourth processor 240 may increase the diagnosis count more as the OCV moving average OCVₘᵥ₁, OCVₘᵥ₂, and/or OCVₘᵥ₃ is less than the threshold moving average.

Based on a degree to which the OCV moving average OCVₘᵥ₁, OCVₘᵥ₂, and/or OCVₘᵥ₃ is less than the threshold moving average, the fourth processor 240 may further calculate a second increment, e.g., 1, to increase the diagnosis count, and diagnose an abnormality of the battery cell 121, 122, and/or 123 based on a result of comparing the increased diagnosis count with the threshold count. For example, based on a degree to which the OCV moving average OCVₘᵥ₁ of the battery cell 121 is less than the threshold moving average, the fourth processor 240 may calculate the second increment, increase the diagnosis count corresponding to the battery cell 121 by the second increment, and diagnose an abnormality of the battery cell 121 based on a result of comparing the increased diagnosis count with the threshold count.

The fourth processor 240 may reduce the diagnosis count when the OCV moving average OCVₘᵥ₁, OCVₘᵥ₂, and/or OCVₘᵥ₃ is greater than or equal to the threshold moving average. For example, the fourth processor 240 may reduce the diagnosis count value corresponding to the battery cell 121 by a first decrement, e.g., 1, when the OCV moving average OCVₘᵥ₁ corresponding to the battery cell 121 is greater than or equal to the threshold moving average. A lower limit of the diagnosis count may be set to a specific value, e.g., 0.

FIG. 3C depicts a graph showing diagnosis counts for each of a plurality of points in time for a battery cell. A horizontal axis indicates time with a scale corresponding to three months, and a vertical axis indicates diagnosis count. A result of increasing or reducing the diagnosis count may be identified based on a result of comparing the OCV moving average 310, obtained by applying a weighted moving average to an OCV deviation variance of the battery cell of FIG. 3B for each of a plurality of points in time, with the threshold moving average 320. Referring back to FIG. 3B, the graph illustrates that the OCV moving average 310 for the battery cell has been less than the threshold moving average 320 since October 2022, such that as shown in FIG. 3C, the graph illustrates that a diagnosis count for the battery cell has increased since October 2022. The diagnosis count corresponding to the battery cell has a value of 100 in April 2023, which means that the diagnosis count corresponding to the battery cell is greater than or equal to the threshold count, resulting in the fourth processor 240 diagnosing that an abnormality occurs in the battery cell.

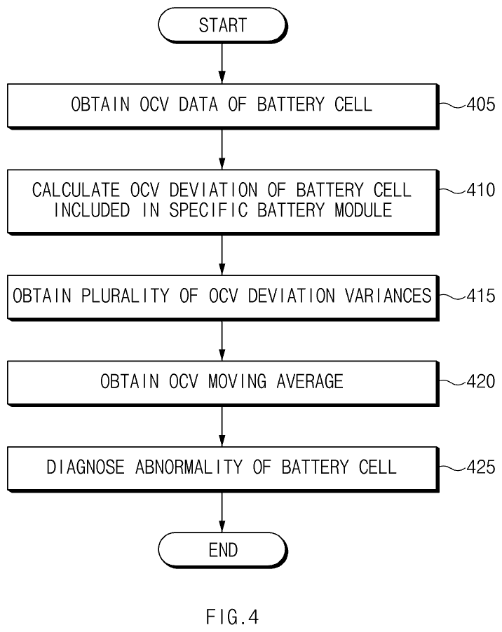

FIG. 4 is an operating flowchart of a battery diagnosis apparatus, such as the battery diagnosis apparatus 150 of FIG. 1 and FIG. 2, according to aspects of the disclosure. Some operations may be omitted, the order of the operations may be changed, and/or some operations may be merged without departing from the scope of the disclosure.

In operation 405, the battery diagnosis apparatus 150 obtains OCV data of the battery cell 121, 122, 123, 131, 132, 133, 141, 142, and/or 143. For example, the battery diagnosis apparatus 150 may configure the OCV data based on voltage, current, and/or temperature measurement information of the battery cell 121, 122, 123, 131, 132, 133, 141, 142, and/or 143. In another example, the battery diagnosis apparatus 150 may receive the OCV data of the battery cell 121, 122, 123, 131, 132, 133, 141, 142, and/or 143, obtained by the battery module 120, 130, or 140 or the battery cell 121, 122, 123, 131, 132, 133, 141, 142, and/or 143.

In operation 410, the battery diagnosis apparatus 150

calculates a plurality of OCV deviations indicating a difference between an average OCV and an OCV of a battery cell based on the OCV data. For example, the battery diagnosis apparatus 150 may extract OCV data in a designated voltage range, e.g., a voltage range of 3.9 V or greater, from the OCV data. The battery diagnosis apparatus 150 may calculate the plurality of OCV deviations based on the extracted OCV data in the designated voltage range.

In operation 415, the battery diagnosis apparatus 150 obtains a plurality of OCV deviation variances indicating degrees of change of a plurality of OCV deviations for a plurality of points in time for a plurality of battery cells based on the plurality of OCV deviations. For example, the plurality of OCV deviation variances may be slopes of the plurality of OCV deviations for each of the plurality of points in time.

In operation 420, the battery diagnosis apparatus 150 obtains an OCV moving average by applying a weighted moving average to the plurality of OCV deviation variances. For example, the battery diagnosis apparatus 150 may apply an exponentially weighted moving average to the plurality of OCV deviation variances. Herein, the plurality of OCV moving averages may corresponding to a battery cell.

In operation 425, the battery diagnosis apparatus 150 diagnoses an abnormality of the battery cell based on the OCV moving average. The battery diagnosis apparatus 150 may diagnose an abnormality of the battery cell based on comparing the OCV moving average with a threshold moving average.

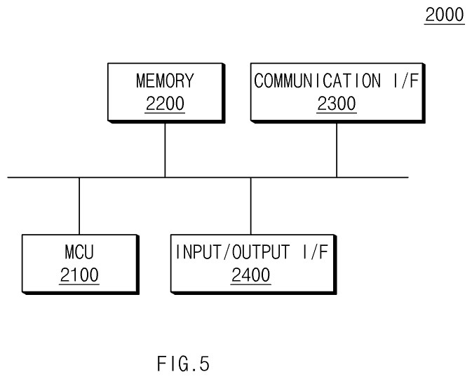

FIG. 5 is a computing system 2000 for implementing the battery diagnosis apparatus according to aspects of the disclosure. The computing system 2000 may include a microcontroller unit (MCU) 2100, a memory 2200, a communication interface (I/F) 2300, and an input/output I/F 2400.

The MCU 2100 may be a processor that executes various programs stored in the memory 2200. The programs may include functions of the battery diagnosis apparatus 150 and/or the operating method of FIG. 4. The memory 2200 may also store various data such as OCV, voltage, current, and/or temperature measurement information

The memory 2200 may be a volatile or nonvolatile memory. Example memory includes random access memory (RAM), dynamic RAM (DRAM), static RAM (SRAM), read only memory (ROM), programmable ROM (PROM), electrically alterable ROM (EAROM), erasable PROM (EPROM), electrically erasable PROM (EEPROM), and/or flash memory. The memory 2200 may be transitory or non-transitory computer readable media storing instructions that are executed by the MCU 2100.

The input/output I/F 2400 may provide an interface for transmitting and receiving data by connecting an input device (not shown), such as a keyboard, a mouse, and/or a touch panel, and an output device (not shown), such as a display, with the MCU 2100.

The communication I/F 2300 is a component capable of transmitting and receiving various data to and from a server. The communication I/F 2300 may include various types of devices capable of supporting wired or wireless communication. For example, a program for a battery diagnosis program may be transmitted and received to and from a separately provided external server through the communication I/F 2300.

Unless otherwise stated, the foregoing alternative examples are not mutually exclusive, but may be implemented in various combinations to achieve unique advantages. As these and other variations and combinations of the features discussed above can be utilized without departing from the subject matter defined by the claims, the foregoing description of the examples should be taken by way of illustration rather than by way of limitation of the subject matter defined by the claims. In addition, the provision of the examples described herein, as well as clauses phrased as “such as,” “including” and the like, should not be interpreted as limiting the subject matter of the claims to the specific examples; rather, the examples are intended to illustrate only one of many possible implementations. Further, the same reference numbers in different drawings can identify the same or similar elements.

What is claimed is:

1. A battery diagnosis apparatus comprising:
an interface configured to obtain open circuit voltage (OCV) data of a battery cell; and
one or more processors configured to:
calculate a plurality of OCV deviations based on the OCV data, the OCV deviations indicating a difference between an average OCV of a plurality of battery cells and an OCV of the battery cell at a plurality of points in time;
calculate a plurality of OCV deviation variances based on the plurality of OCV deviations, the OCV deviation variances indicating a degree of change of the plurality of OCV deviations at the plurality of points in time;
calculate an OCV moving average based on the plurality of OCV deviation variances by applying a weighted moving average to the plurality of OCV deviation variances; and
diagnose an abnormality of the battery cell based on the OCV moving average.

2. The battery diagnosis apparatus of claim 1, wherein the one or more processors are further configured to:
determine that a k^{th} OCV deviation variance corresponding to a k^{th} point in time among the plurality of points in time is less than a first threshold OCV deviation variance;
determine that a (k−1)^{th} OCV deviation corresponding to a (k−1)^{th} point in time previous to the k^{th} point in time is greater than or equal to a threshold OCV deviation; and
change the kth OCV deviation variance into a predetermined OCV deviation variance;
wherein applying the weighted moving average to the plurality of OCV deviation variances comprises the predetermined OCV deviation variance.

3. The battery diagnosis apparatus of claim 1, wherein diagnosing an abnormality of the battery cell comprises comparing the OCV moving average with a threshold moving average.

4. The battery diagnosis apparatus of claim 3, wherein the one or more processors are further configured to:
determine that the OCV moving average is less than the threshold moving average; and
increase a diagnosis count by a first increment;
wherein diagnosing an abnormality of the battery cell is based on comparing the diagnosis count with a threshold count.

5. The battery diagnosis apparatus of claim 4, wherein the one or more processors are further configured to:
calculate a second increment based on a degree to which the OCV moving average is less than the threshold moving average; and
increase the diagnosis count by the second increment.

6. The battery diagnosis apparatus of claim 4, wherein the one or more processors are further configured to:
determine that the OCV moving average is greater than or equal to the threshold moving average; and
reduce the diagnosis count.

7. The battery diagnosis apparatus of claim 1, wherein the one or more processors are further configured to:
determine that an OCV deviation variance is less than a second threshold OCV deviation variance; and
change the OCV deviation variances less than the second threshold OCV deviation variance to the second threshold OCV deviation variance;
wherein applying the weighted moving average to the plurality of OCV deviation variances comprises OCV deviation variance changed to the second threshold OCV deviation variance.

8. The battery management apparatus of claim 1, wherein the weighted moving average is an exponentially weighted moving average.

9. The battery diagnosis apparatus of claim 1, wherein the OCV data compensates for a balancing process performed on the battery cell based on a balancing capacity.

10. The battery diagnosis apparatus of claim 9, wherein the balancing capacity corresponds to an accumulated discharging capacity from the balancing process over a period of time.

11. A battery diagnosis method comprising:
receiving, by one or more processors, open circuit voltage (OCV) data of a battery cell;
calculating, by the one or more processors, a plurality of OCV deviations based on the OCV data, the OCV deviations indicating a difference between an average OCV of a plurality of battery cells and an OCV of the battery cell at a plurality of points in time;
calculating, by the one or more processors, a plurality of OCV deviation variances based on the plurality of OCV deviations, the OCV deviation variances indicating a degree of change of the plurality of OCV deviations at the plurality of points in time;
calculating, by the one or more processors, an OCV moving average based on the plurality of OCV deviation variances by applying a weighted moving average to the plurality of OCV deviation variances; and
diagnosing, by the one or more processors, an abnormality of the battery cell based on the OCV moving average.

12. The method of claim 11, further comprising:
determining, by the one or more processors, that a k^{th} OCV deviation variance corresponding to a k^{th} point in time among the plurality of points in time is less than a first threshold OCV deviation variance;
determining, by the one or more processors, that a (k−1)^{th} OCV deviation corresponding to a (k−1)^{th} point in time previous to the k^{th} point in time is greater than or equal to a threshold OCV deviation; and
changing, by the one or more processors, the kth OCV deviation variance into a predetermined OCV deviation variance;
wherein applying the weighted moving average to the plurality of OCV deviation variances comprises the predetermined OCV deviation variance.

13. The method of claim 11, wherein diagnosing an abnormality of the battery cell comprises comparing the OCV moving average with a threshold moving average.

14. The method of claim 13, further comprising:
determining, by the one or more processors, that the OCV moving average is less than the threshold moving average; and
increasing, by the one or more processors, a diagnosis count by a first increment;
wherein diagnosing an abnormality of the battery cell is based on comparing the diagnosis count with a threshold count.

15. The method of claim 14, further comprising:
calculating, by the one or more processors, a second increment based on a degree to which the OCV moving average is less than the threshold moving average; and
increasing, by the one or more processors, the diagnosis count by the second increment.

16. The method of claim 14, further comprising:
determining, by the one or more processors, that the OCV moving average is greater than or equal to the threshold moving average; and
reducing, by the one or more processors, the diagnosis count.

17. The method of claim 11, further comprising:
determining, by the one or more processors, that an OCV deviation variance is less than a second threshold OCV deviation variance; and
changing, by the one or more processors, the OCV deviation variances less than the second threshold OCV deviation variance to the second threshold OCV deviation variance;
wherein applying the weighted moving average to the plurality of OCV deviation variances comprises OCV deviation variance changed to the second threshold OCV deviation variance.

18. The method of claim 11, wherein the weighted moving average is an exponentially weighted moving average.

19. The method of claim 11, wherein the OCV data compensates for a balancing process performed on the battery cell based on a balancing capacity, the balancing capacity corresponding to an accumulated discharging capacity from the balancing process over a period of time.

20. A non-transitory computer readable medium storing instructions that, when executed by one or more processors, cause the one or more processors to perform a battery diagnosis method, the method comprising:
receiving open circuit voltage (OCV) data of a battery cell;
calculating a plurality of OCV deviations based on the OCV data, the OCV deviations indicating a difference between an average OCV of a plurality of battery cells and an OCV of the battery cell at a plurality of points in time;
calculating a plurality of OCV deviation variances based on the plurality of OCV deviations, the OCV deviation variances indicating a degree of change of the plurality of OCV deviations at the plurality of points in time;
calculating an OCV moving average based on the plurality of OCV deviation variances by applying a weighted moving average to the plurality of OCV deviation variances; and
diagnosing an abnormality of the battery cell based on the OCV moving average.
